(19) United States
(12) Patent Application Publication
(10) Pub. No.: US 2022/0237495 A1
(43) Pub. Date: Jul. 28, 2022

(54) INTERCONNECTIONS BETWEEN QUANTUM COMPUTING MODULE AND NON-QUANTUM PROCESSING MODULES IN QUANTUM COMPUTING SYSTEMS

(71) Applicant: SeeQC, Inc., Elmsford, NY (US)

(72) Inventors: Daniel Yohannes, Elmsford, NY (US); Igor Vernik, Elmsford, NY (US); Caleb Jordan, Elmsford, NY (US); Patrick Truitt, Elmsford, NY (US); Alex Kirichenko, Elmsford, NY (US); Amir Jafari Salim, Elmsford, NY (US); Naveen Katam, Elmsford, NY (US); Oleg Mukhanov, Elmsford, NY (US)

(21) Appl. No.: 17/501,897

(22) Filed: Oct. 14, 2021

Related U.S. Application Data
(63) Continuation of application No. PCT/US21/54828, filed on Oct. 13, 2021.
(60) Provisional application No. 63/091,455, filed on Oct. 14, 2020.

(51) Int. Cl. G06N 10/40; H01L 39/22; G06N 10/20

(52) U.S. Cl. CPC G06N 10/40; G06N 10/20; H01L 39/223

(57) ABSTRACT

The technology disclosed in this patent document can be implemented to combine quantum computing, classical qubit control/readout, and classical digital computing in a scalable computing system based on superconducting qubits and special interconnection designs for connecting hardware components within a multi-stage cryogenic system to provide fast communications between the quantum computing module and its controller while allowing efficient management of wiring with other modules.

### PRIORITY CLAIMS AND RELATED APPLICATION

This patent document claims priority to and benefits of U.S. Provisional Patent Application No. 63/091,455 entitled “INTERCONNECTION BETWEEN QUANTUM COMPUTING MODULE AND NONQUANTUM PROCESSING MODULES IN QUANTUM COMPUTING SYSTEMS” filed by Applicant SeeQC, Inc. at the U. S. Patent and Trademark Office on Oct. 14, 2020 (Attorney Docket No. 133858-8002.US00), the entire disclosure of which is incorporated by reference as part of this patent document.

### TECHNICAL FIELD

This patent document relates to computing or information processing systems including quantum computing modules performing information processing or computing using quantum states of quantum mechanical devices or circuits.

### BACKGROUND

Classical digital computers, including general purpose digital computers and high-performance digital supercomputers, perform computations based on Boolean logic. Computing technologies based on Boolean logic have revolutionized a wide range of industries and technologies for recent decades but have also exhibited certain limitations in performing highly complex or large numbers of computations, such as molecular modeling of structures and properties of chemical compounds or biological structures, cryptography, or modeling of complex systems for weather forecast, climate changes and others. Various new computation techniques have been investigated to supplement or replace Boolean logic based digital computing.

Quantum-mechanical systems can be used to construct new computation systems for complex information processing. A quantum system suitable for quantum computing has an ensemble of subsystems exhibiting different quantum states where subsystems are correlated or “entangled” with one another due to quantum coherence, including long-range quantum coherence. In various implementations for quantum computers, each subsystem in the ensemble of subsystems may be a quantum system exhibiting two or more different quantum states to operate as a fundamental quantum device and information can be represented, stored, processed, and transmitted by superposition and correlation of quantum states of different fundamental quantum devices. One example of such a fundamental quantum device is a two-state device known as a quantum bit (“qubit”). Some examples of implementations of qubits include superconducting qubits based on superconducting Josephson junctions developed at IBM, Google, Intel and others, ion trap devices based on electromagnetic trapping fields by laser beams developed at Honeywell and IonQ, semiconductor-based quantum dots and other devices capable of quantum computing operations.

### SUMMARY

The technology disclosed in this patent document can be implemented to combine quantum computing and classical digital computing in a scalable computing system based on superconducting qubits using Josephson junctions that exhibit low dissipation, long coherence times and can be fabricated with well-developed integrated circuit fabrication techniques. It is well known that quantum computers based on superconducting qubits are complex due to various requirements for providing and maintaining superconducting qubits devices or systems, requiring complex and bulky cryogenic systems and using special superconducting materials. In recognition of those technical complexities and challenges for scalable commercial applications, the disclosed technology provides hybrid quantum-classical computing architectures and configurations that strategically partition and combine hardware for quantum computing and hardware for classical digital computing and place such hardware components in certain ways within multi-stage cryogenic system to produce scalable hybrid quantum-classical computing systems for commercial applications. The disclosed technology can be implemented by using special interconnection designs for connecting hardware components within a multi-stage cryogenic system.

In one aspect, the disclosed technology can be implemented to provide a system capable of information processing based at least in part on quantum computing using quantum states of quantum bits. This system includes a cryostat system structured to include different cryogenic stages operable to provide a low cryogenic temperature and higher cryogenic temperatures; and a quantum computing module enclosed by the cryostat system at the low cryogenic temperature, the quantum computing module comprising a first integrated chip structured to support a plurality of quantum bit circuits. Each quantum bit circuit is structured as a superconducting circuit at the low cryogenic temperature to exhibit different quantum states as a quantum-mechanical system and to quantum-mechanically interact with other quantum bit circuits via quantum entanglement to cause superposition or correlation of different quantum states of the quantum bit circuits. This system includes a quantum bit management circuit module enclosed by the cryostat system, located adjacent to the quantum computing module and coupled to be maintained at a cryogenic temperature, quantum bit control circuits supported by a second integrated chip and structured to direct control signals to the quantum bit circuits to control the quantum bit circuits, respectively, and quantum bit readout circuits supported by the second integrated chip and structured to output readout signals from the quantum bit circuits, respectively, the readout signals representing quantum states of the quantum bit circuits, respectively, the quantum bit control circuits and quantum bit readout circuits structured to include superconducting circuits at the low cryogenic temperature and operable to operate with the control signals and readout signals based on digital processing and in a non-quantum classical manner, and wherein the second integrated chip is engaged to the first integrated chip to form a multichip module to transfer control signals and readout signals therebetween. This system further includes circuit modules enclosed by the cryostat system at the higher cryogenic temperatures and structured to communicate with the quantum bit management circuit module in connection with the control signals and readout signals; electrically conductive bumps formed to engage the first and second integrated chips to each other; and electrically conductive wires coupled between the quantum bit management circuit module and at least one of the circuit modules situated at higher temperature stages of the cryostat system to provide communications and transfer signals therebetween.

In another aspect, the disclosed technology can be implemented to provide a method for processing information processing based at least in part on quantum computing using quantum states of quantum bits. This method includes operating a quantum computing module comprising a plurality of quantum bit circuits operable to exhibit different quantum states as a quantum-mechanical system to cause to quantum-mechanically interactions amongst the quantum bit circuits to cause superposition or correlation of different quantum states of the quantum bit circuits; causing quantum bit control circuits to direct control signals to the quantum bit circuits to control the quantum bit circuits, respectively; operating quantum bit readout circuits to output readout signals from the quantum bit circuits, respectively, the readout signals representing quantum states of the quantum bit circuits, respectively; thermally coupling the quantum bit circuits, the quantum bit control circuits and quantum bit readout circuits to a common cryogenic stage; coupling the quantum bit circuits, the quantum bit control circuits and quantum bit readout circuits via capacitive coupling or inductive coupling to apply the control signals from the quantum bit control circuits to the quantum bit circuits, respectively; and using electrically conductive wires coupled between the quantum bit management circuit module and one or more circuit modules at one or more higher temperatures than a temperature of the common cryogenic stage coupled to the quantum bit circuits, the quantum bit control circuits and quantum bit readout circuits to transmit information in connection with operating the quantum bit circuits, the quantum bit control circuits and quantum bit readout circuits.

In yet another aspect, the disclosed technology can be implemented to provide a system capable of information processing based at least in part on quantum computing using quantum states of quantum bits. This system includes a cryostat system structured to include different cryogenic stages operable to provide a low cryogenic temperature and higher cryogenic temperatures and a quantum computing module enclosed by the cryostat system at the low cryogenic temperature. The quantum computing module comprising a first integrated chip structured to support a plurality of quantum bit circuits and each quantum bit circuit is structured as a superconducting circuit at the low cryogenic temperature to exhibit different quantum states as a quantum bit and to quantum mechanically interact with other quantum bit circuits to cause correlation (superposition or entanglement) of different quantum states and parts of the quantum bit circuits. This system includes a quantum bit management circuit module enclosed by the cryostat system, located adjacent to the quantum computing module and coupled to it to be maintained at the same low cryogenic temperature as with the quantum computing module, the quantum bit management circuit structured to include a second integrated chip, quantum bit control circuits supported by a second integrated chip and structured to direct control signals to the quantum bit circuits to control the quantum bit circuits, respectively, and quantum bit readout circuits supported by the second integrated chip and structured to output readout signals from the quantum bit circuits, respectively. The readout signals represent quantum states of the quantum bit circuits, respectively, and the quantum bit control circuits and quantum bit readout circuits are structured to include superconducting circuits at the low cryogenic temperature and operable to operate with the control signals and readout signals based on digital processing and in a non-quantum classical manner, and wherein the second integrated chip is engaged to the first integrated chip to form a multichip module to transfer control signals and readout signals there between. This system further includes circuit modules enclosed by the cryostat system at the higher cryogenic temperatures and structured to communicate with the quantum bit management circuit module in connection with the control signals and readout signals; electrically conductive bumps formed to connect the first and second integrated chips, at least part of which form electrical conductive paths between the quantum bit management circuit module and quantum computing module for transfer of part of the control signals and readout signals without using other wiring between the quantum bit management circuit module and quantum computing module; and electrically conductive wires coupled between the quantum bit management circuit module and at least one of the circuit modules to provide communications and transfer signals therebetween.

This and other aspects, and their implementations are described in greater detail in the drawings, the description and the claims.

### BRIEF DESCRIPTION OF DRAWINGS

FIG. 1A, 1B, 1C, 1D and 1E show examples of quantum computing systems based on the disclosed technology and interconnection designs for connecting different hardware modules within a multistage cryogenic system.

FIGS. 2, 3A, 3B and 3C show examples of interconnection wires and electrical isolation structures

FIGS. 4A, 4B and 4C show examples of a segment of an MCM structure for the quantum bit management circuit module and quantum computing module being mechanically and electrically connected via superconducting bumps.

FIG. 4D shows an example of a plot showing a result of simulated coupling between the strip lines for each of the three depicted in FIGS. 4A, 4B, and 4C (curves 1-3, respectively).

FIG. 5A shows an example of an MCM device showing more detailed layouts of the quantum bit management circuit module and quantum computing module with an asymmetric flux bias feed line.

FIG. 5B shows an example of an MCM device showing more detailed layouts of the quantum bit management circuit module and quantum computing module with a symmetric flux bias feed line.

FIG. 5C shows another example for implementing an MCM module for quantum bit management circuit module and quantum computing module in which the readout resonator for each qubit is located on the quantum bit management circuit module.

FIGS. 6 and 7 show an example of a JPM-SFQ Comparator MCM.

FIG. 8 shows an example for capacitive coupling between a qubit and an SFQ chip via a passive transmission line (PTL) and an overlap capacitor.

FIG. 9 shows an example of capacitive coupling between a qubit and an SFQ chip.

### DETAILED DESCRIPTION

The technology disclosed herein for computing or information processing systems with superconductor-based quantum computing modules (e.g., superconducting Josephson junctions) can be implemented by combining quantum computing modules or devices and classical digital computing modules or devices in ways that allow the systems to be scalable for complex computing applications and by strategically partitioning such systems into different quantum and classical digital computing modules, devices or components at various cryogenic stages at different cryogenic temperatures to achieve superconducting conditions at those cryogenic stages. Such implementations of the disclosed technology can be used to simplify and reduce the complex and bulky cryogenic systems commonly used in various quantum computer systems using superconducting quantum computing devices and to reduce the use or level of use of complex superconducting cabling systems for linking different computing or processing modules. Implementations of the disclosed technology can be devised to allow for commercially scalable fabrication using integrated circuit (IC) fabrication processes and equipment in manufacturing key modules or devices for quantum computer systems based on superconducting Josephson junctions. The technology disclosed in this patent document can be implemented to provide special interconnection designs for connecting hardware components within a multi-stage cryogenic system to provide fast communications between the quantum computing module and its controller while allowing efficient management of wiring with other modules.

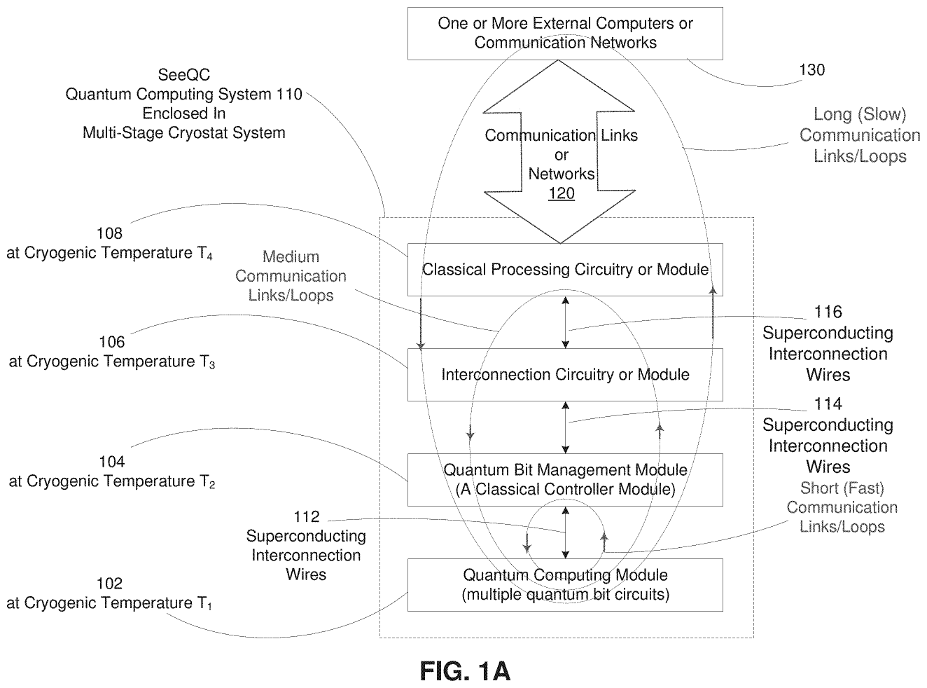

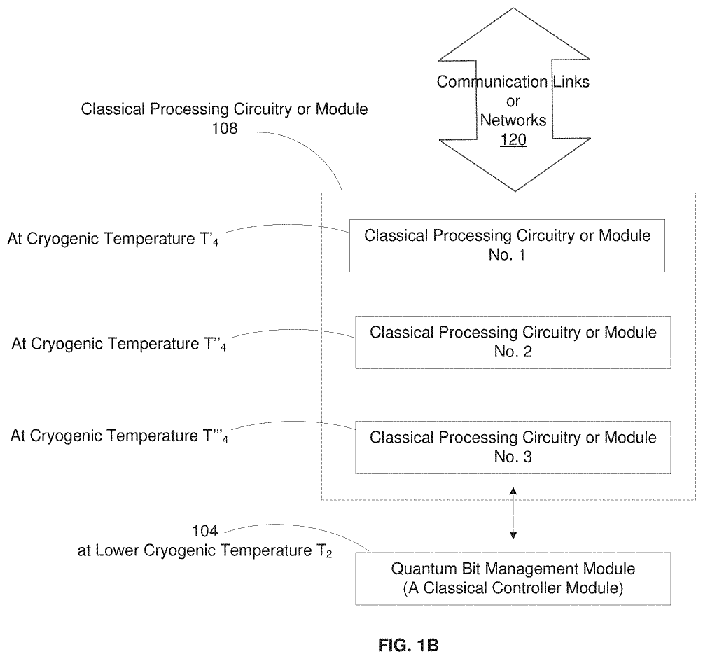

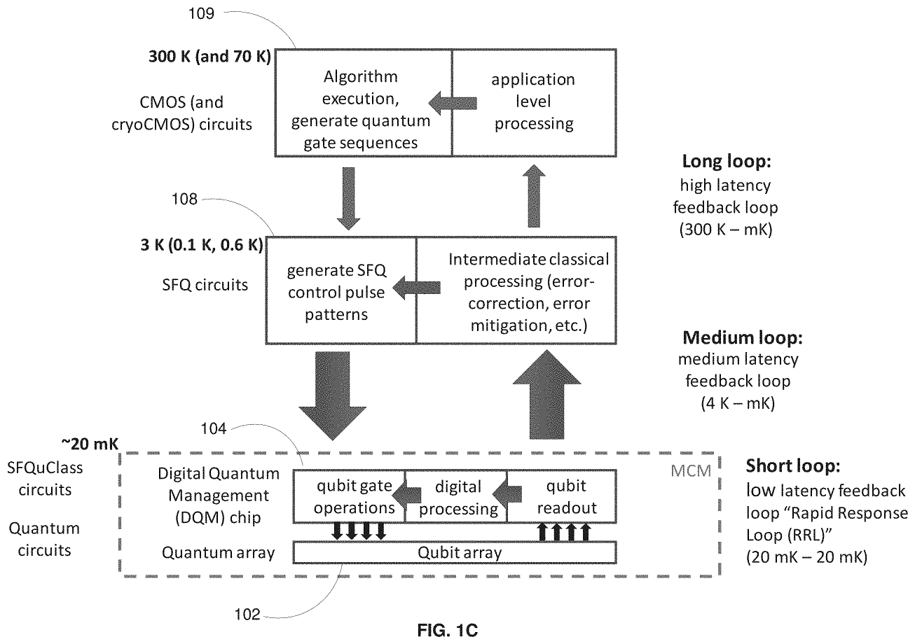

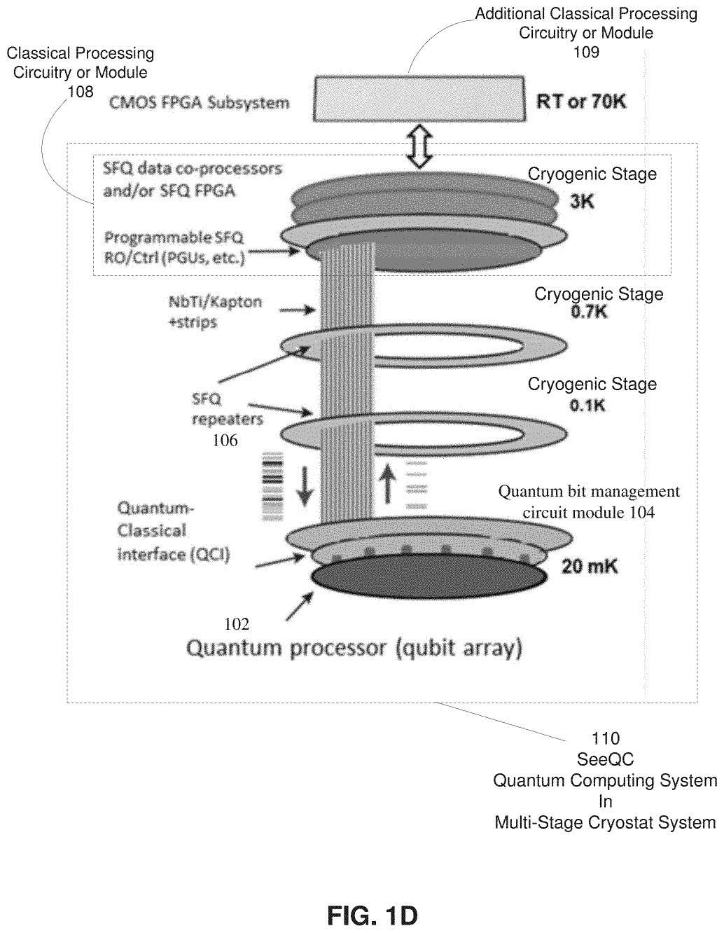

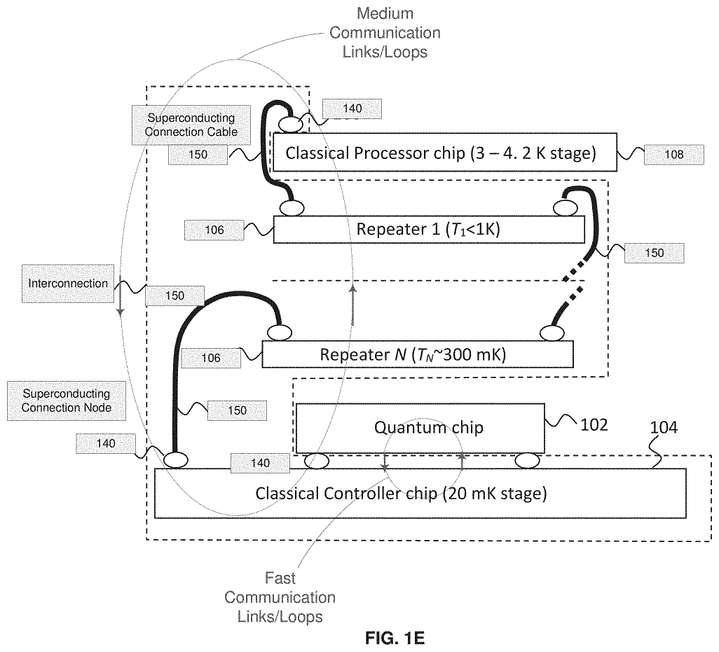

FIGS. 1A, 1B, 1C, 1D and 1E show examples for implementing quantum computing systems based on the disclosed technology and interconnection designs for connecting different hardware modules within a multistage cryogenic system.

FIG. 1A shows an example of a quantum computing system 110 to produce scalable hybrid quantum-classical computing systems for commercial applications. The quantum computing system 110, as its name implies, includes multiple qubit circuits and performs computing operations based on quantum states of the qubit circuits and is in communications with external computers or computing systems 130 via the communication links or networks 120. The communication links and networks 120 may include circuits where signals are transferred in the form of electromagnetic signals, including for example, electric signals carried by electrically conductive wires and/or optical signals. In operation, the quantum computing system 110 receives computation requests or tasks from one or more external computers or computing systems 130, performs the requested computation operations and sends the computation results back to the one or more requesting external computers or computing systems 130. The communications and/or interactions between the quantum computing system 110 and external computers or computing systems 130 are via the communication links or networks 120 and may constitute the longest communication cycle in time in the operations of the quantum computing system 110 and is labeled as the long communication links or loops. As further explained below, the quantum computing system 110 is structured to partition different internal computing modules so that those internal computing modules communicate via internal shorter communication links or loops such as medium communication links or loops with medium delays in time and fast communication links or loops with the shortest delays in time.

The quantum computing system 110 includes a multi-stage cryogenic system to provide different cryogenic stages at different locations and to maintain at different cryogenic temperatures for keeping different modules or devices at their respective desired temperatures (e.g., T₁, T₂, T₃ and T₄ as shown). In some implementations, the different cryogenic stages may be designed to produce temperatures from milli Kelvins to tens of Kelvins. This example system 110 includes a quantum computing module 102 that includes multiple qubit circuits or devices as the quantum qubit ensemble to perform desired quantum computing operations via their respective qubit states. In many implementations, the quantum computing module 102 is engaged or coupled to a cryogenic stage at a low cryogenic temperature T₁ to ensure that qubit circuits or devices are under the desired superconducting condition and under acceptable quantum computing operating conditions at which the noise level and interference level are sufficiently low. A quantum bit management circuit module 104 is provided to be in communications with the quantum computing module 102 to provide control signals to the individual qubit circuits or devices of the quantum computing module 102 and to read out the individual qubit circuits or devices and may be implemented by using non-quantum mechanical processing circuitry such as digital circuitry or analogy circuitry or a combination of digital and analog circuitry. The quantum bit management circuit module 104 may be implemented with superconducting circuitry and is coupled to a cryogenic stage at a cryogenic temperature T₂ which may be different from the low cryogenic temperature T₁ in some implementations or be the same as the temperature T₁ in other implementations. As further explained below, in some designs, the quantum computing module 102 and quantum bit management circuit module 104 may be engaged to share a common cryogenic stage so that both modules are kept at the same cryogenic temperature. The quantum bit management circuit module 104 can be structured to include (1) quantum bit control circuits to direct control signals to the quantum bit circuits to control the quantum bit circuits, respectively, and (2) quantum bit readout circuits to output readout signals from the quantum bit circuits, respectively. In this example, the quantum computing module 102 and quantum bit management circuit module 104 together form the “heart” or “core” of the quantum computing system 110 in part because the quantum computing operations are performed within the quantum computing module 102 based on the control signals to qubit circuits from the quantum bit management circuit module 104 and the readouts of the qubit circuits are performed by the quantum bit management circuit module 104. The communications between the quantum computing module 102 and quantum bit management circuit module 104 are essential to the quantum computing operations in terms of the quality and speed of such communications. Accordingly, in implementations, the quantum computing module 102 and quantum bit management circuit module 104 can be placed or positioned physically close to or adjacent to each other to shorten signal paths between the two modules 102 and 104 and to reduce any interference or noise to such communications. In addition, the functions or operations of the quantum bit management circuit module 104 may, by an intentional design, be limited to certain core functions or operations in connection with the quantum computations performed by the quantum computing module 102 so that the quantum bit management circuit module 104 can achieve a short or fast response or processing time to ensure fast input/output signaling at the quantum computing module 102. This intentional reduced function design consideration for the quantum bit management circuit module 104 is also based on the desire to reduce the power consumption and energy dissipation by the quantum bit management circuit module 104 to its surroundings in light of its close proximity to the quantum computing module 102, the noise or interference by the quantum bit management circuit module 104 to the quantum computing module 102 and the need for maintaining proper cryogenic conditions at the both the quantum bit management circuit module 104 and the adjacent quantum computing module 102. Based on the above and other considerations, the interconnections and signal paths between the two modules 102 and 104 are designed to form the fast communication link or loop with the shortest delay in time for the quantum computing system 110. For example, in some implementations, the quantum computing module 102 may include at least one integrated chip supporting one or plurality of quantum bit circuits, and the quantum bit management circuit module 104 may be formed on another integrated chip which is directly coupled to the integrated chip with the quantum bit circuits, mechanically and electrically, as a multichip module via superconducting bumps, capacitive coupling, or magnetic coupling via vacuum to transfer control signals and readout signals therebetween. This multichip module formed by the two modules 102 and 104 can be coupled to the same cryogenic stage at the low cryogenic temperature T₁. This design can be commercially important because the chip fabrication for the multichip module formed by the two modules 102 and 104 is a scalable platform to allow a wide range of quantum bit circuits to be fabricated and included in the quantum computing module 102 and, similarly, the quantum bit management circuit module 104 may also be scaled based on the number of quantum bit circuits present.

The quantum computing system 110 in FIG. 1A further includes a digital processing module 108 that provides certain signal and data processing functions or operations for the quantum computing system 110 in connection with quantum computations performed by the quantum computing module 102 via the quantum bit management circuit module 104. In this regard, the digital processing module 108 forms the core processing module for non-quantum computation and/or processing functions within the quantum computing system 110 and thus is designed with much more complex circuitry and higher processing capabilities than the quantum bit management circuit module 104. Specifically, certain functions and/or processing operations that cannot be built into the quantum bit management circuit module 104 may be included in the circuitry of the digital processing module 108. In addition, the digital processing module 108 also functions as an interface between the quantum computing system 110 and one or more external computers or computing systems 130 via the communication links or networks 120. As such, the digital processing module 108 is designed to further include processing functions associated with communications and interactions between the quantum computing system 110 and external computers or computing systems 130. Therefore, different from the placement and design of the quantum bit management circuit module 104, the digital processing module 108 is designed to be a complex and capable classical counterpart and co-processor of the quantum computing module 102 of the quantum computing system 110. The increased functions and/or processing operations and processing capabilities packed into the digital processing module 108 add to the complexity and size of the circuitry of the digital processing module 108 and further increase the power consumption and energy dissipation of the digital processing module 108. Therefore, it is desirable to place the digital processing module 108 physically away from the quantum computing module 102 and its adjacent neighbor quantum bit management circuit module 104 to reduce the noise and interference that the digital processing module 108 may impose onto the quantum computing module 102. The digital processing module 108 may be designed with various functions and capabilities, including, e.g., error correction functions for the quantum computing system 110, and non-quantum computation and/or processing functions within the quantum computing system 110, including, e.g., functions in connection with the control of and readout of the quantum computing module 102 performed by the quantum bit management circuit module 104, and management of data of the quantum computations performed by the quantum computing module 102. In some implementations, the digital processing module 108 may be coupled to a cryogenic stage at a temperature T₄ higher than those for the quantum computing module 102 (at T₁) and quantum bit management circuit module 104 (at T₁ or T₂). The digital processing module 108 may be designed to include superconducting circuitry and is enclosed within the multi-stage cryogenic system of the quantum computing system 110.

The intentional design for placing the digital processing module 108 away from the quantum bit management circuit module 104 leads to longer signal paths or links between the digital processing module 108 and the quantum bit management circuit module 104. Within the enclosure of the multi-stage cryogenic system, such signal paths or links may be formed by using superconducting wires or cables. Notably, the long lengths of such signal paths or links may cause a certain degree of signal degradation and one option for addressing this is to add one or more interconnection repeaters or signal conditioning circuits 106 between the digital processing module 108 and the quantum bit management circuit module 104 to condition the signals. Like other modules within the multi-stage cryogenic system, each interconnection repeater or signal conditioning circuit 106 may be engaged or coupled to a cryogenic stage at a temperature T₃ higher than the temperature of the quantum bit management circuit module 104 (at T₁ or T₂) and lower than the temperature of the digital processing module 108 (at T₄). For example, a digital signal conditioning circuit module 106 may include a superconducting circuit which conditions the control signals or the readout signals.

In some implementations, the quantum computing system 110 may further include a digital processing subsystem 109 outside the multistage cryogenic system or the cryostat system to communicate with the digital processing module 108 to perform an operation associated with supporting execution of quantum or quantum-classical algorithms and/or communication with one or more other computers or networks 130. This is shown in the examples in FIGS. 1C and 1D. This digital processing subsystem 109 outside the cryostat system may include one or more CMOS digital processors, one or more field-programmable gate arrays (FPGAs), or one or more application specific integrated circuits (ASICs), or one or more central processing units (CPUs).

The quantum processing performed by the quantum computing module 102 is the core of the quantum computing system 110 and the signaling and communications between the quantum computing module 102 and the rest of the system 110 play a significant role in the overall computing speed and performance of the system 110. The latencies in the signaling and communications between the quantum computing module 102 and the rest of the system 110 are important parameters to optimize in order to achieve scalable hybrid quantum-classical computing systems for commercial applications. During operation, information is passed between the quantum computing module 102 and the other processing modules and computing entities involved in the computation performed in the quantum computing system 110. As illustrated, different communication links and/or feedback loops are formed between the quantum computing module 102 and the non-quantum modules and others in the system 110. The fastest link/loop, labelled as the short loop in FIG. 1A, is between the quantum computing module 102 and the quantum bit management circuit module 104. This link/loop can be compared with the communication link/loop formed between the quantum computing module 102 and the digital processing module 108, which experiences a longer latency as 1) communication between these modules must traverse a longer distance, including passing through the quantum bit management module 104 which may perform its own operations on the data cycling between the quantum computing module 102 and digital processing module 108, and 2) the digital processing module 108 in general performs more complex processing operations. Thus, in FIG. 1A, communication between 102 and 108 is labelled as a medium communication link/loop. An even longer latency occurs between the quantum computing module 102 and external computers or computing systems 130, labelled as a long communication link/loop in FIG. 1A, again due to increased distance (encompassing both the communication paths and possible operations of the short and medium loops plus the communication links or networks 120) and complexity of processing operations as compared to the medium link/loop.

Therefore, the example of the quantum computing system 110 in FIG. 1A includes special design features to provide a hybrid computing environment that combines processing functions and/or operations by the quantum computing part (e.g., the quantum computing module 102) and non-quantum classical processing part (e.g., the quantum bit management circuit module 104 and digital processing module 108) and to strategically partition and allocate different amounts and types of processing functions and/or operations of the non-quantum classical processing part between the quantum bit management circuit module 104 and the digital processing module 108 in light of the intentional design for placing the quantum bit management circuit module 104 physically placed close to the quantum computing module 102 while distancing the quantum computing module 102 from the digital processing module 108.

In some implementations, the digital processing module 108 may be designed to include two or more different processing modules to optimize the computation speed and performance of the digital processing module 108. For example, the digital processing module 108 may be further divided into a series of modules, as shown in FIG. 1B, with different temperature stages of the cryogenic system housing one or more such modules. In general, the design of the quantum computing system 110 in FIG. 1A allows for optimization in placement of each module within the cryogenic system so as to balance its particular needs with respect to low latency (which favors close proximity to the quantum module 102) and ability to handle dissipation during processing operations (which favors higher temperature stages that are placed further away from the quantum module 102), as well as to make efficient use of the volume of the cryogenic system.

FIG. 1C shows an example for executing certain processing operations at different modules in the system 110 in FIG. 1A, specifically showing processing operations in the digital processing module 108, processing operations in the additional digital processing module 109 operated at a higher temperature than that of the digital processing module 108 and processing operations in the quantum bit management circuit module 104. As a specific example, FIG. 1C shows that desired quantum gate sequences produced by the additional digital processing module 109 based on information from the digital processing module 108 in light of the qubit readout from the quantum bit management circuit module 104 are sent to, and are processed by, the digital processing module 108 to generate SFQ control pulse patterns. The quantum bit management circuit module 104 receives such SFQ control pulse patterns to apply the received SFQ control pulse patterns and/or flux biases to the quantum module 102 to set the relevant qubits into the quantum gate sequences. This is an example for implementing the medium communication loop in FIG. 1A, communication between quantum computing module 102 and digital processing module 108 that includes the links with the quantum bit management module 104 or any interconnection module 106 between the modules 102 and 108. FIG. 1C further shows an example for implementing the short communication loop between the quantum bit management module 104 and the quantum computing module 102 where the qubit readout obtained from reading out the quantum computing module 102 is digitally processed by the quantum bit management module 104 and the processed information is further used by the quantum bit management circuit module 104 to apply SFQ control pulse patterns and/or flux biases to the quantum module 102.

In various implementations, the quantum computing module 102 and non-quantum classical processing part (e.g., the quantum bit management circuit module 104 and the digital processing module 108) are structured to include superconducting circuits or devices coupled to different cryogenic stages of the multistage cryogenic system and superconducting interconnection wires 112, 114 and 116 are provided and maintained at temperatures at different locations to transfer signals between different modules or stages. The multi-stage cryogenic system for the quantum computing system 110 may be implemented in various configurations including multi-stage dilution refrigerators whose operation principle is based on mixing of helium-3 and helium-4 to provide the different cryogenic stages at the different graded cryogenic temperatures. In some implementations, the cryostat system may include a nuclear demagnetization refrigerator or adiabatic demagnetization refrigerator.

The modules within the quantum computing system 110 may be implemented in various configurations. For example, each quantum bit circuit for the qubits in the quantum computing module 102 may include a superconducting Josephson junction circuit or a switching superconducting circuit different from a Josephson junction circuit. For example, the quantum bit management circuit module 104 may be implemented to include a superconducting Josephson junction circuit or single flux quantum (SFQ) logic circuit, or a quantum flux parametron circuit such as an adiabatic quantum flux parametron circuit, or a nanowire switch, or a superconducting ferromagnetic transistor, or a superconducting spintronic device, or a field-effect superconducting device. The digital processing module 108 may be implemented to include SFQ circuitry, field-programmable gate arrays (FPGAs), or one or more application specific integrated circuits (ASICs).

In the system in FIG. 1A, optical communication links may be used for transfer of signals, either as a replacement for certain electrically conductive wires or cables or as additional links in combination with electrically conductive wires or cables. An optical communication link can provide faster data transmission and increase the communication bandwidth. For example, optical communication can be used between the cryogenic stage with the highest temperature stage (e.g., the module 108 in FIG. 1A) and a room temperature stage. In implementations, optical transmitter and receiver devices are provided in such stages or circuit modules to enable transmission and reception of optical signals between the cryogenic stages situated at the highest temperature of the cryostat system and the room temperature electronics to provide communications therebetween. In some implementations, such optical communication links may be implemented between the module 108 and the CMOS FPGA subsystem.

FIG. 1D shows an example of a quantum computing system that is capable of information processing based at least in part on quantum computing using quantum states of quantum bits based on the design in FIG. 1A. The cryostat system in this example is structured and operable to provide different cryogenic stages at different temperatures—20 mK, 0.1K, 0.7K, and 3K. Different circuit modules at the different cryogenic stages are interconnected by superconducting wires such as NbTi/Kapton (NbTi/polyamide) strips. The quantum computing module enclosed by the cryostat system includes a first integrated chip structured to support quantum bit circuits. Each quantum bit circuit is structured as a superconducting circuit to exhibit different quantum states as a quantum bit and to quantum mechanically interact with other quantum bit circuits via quantum entanglement to cause superposition or correlation of different quantum states of the quantum bit circuits. The quantum bit management circuit 104 module is located adjacent to the quantum computing module 102 and is coupled to be maintained at the same low cryogenic temperature as with the quantum computing module. The quantum bit management circuit includes a second integrated chip, quantum bit control circuits supported by the second integrated chip and structured to direct control signals to the quantum bit circuits to control the quantum bit circuits, respectively, and quantum bit readout circuits supported by the second integrated chip and structured to output readout signals from the quantum bit circuits, respectively. In operation, the readout signals represent quantum states of the quantum bit circuits, respectively, the quantum bit control circuits and quantum bit readout circuits are structured to include superconducting circuits and operable to operate with the control signals and readout signals based on digital processing and in a non-quantum classical manner. Notably, the second integrated chip is engaged to the first integrated chip to form a multichip module (MCM) to transfer control signals and readout signals.

FIG. 1E shows an example for implementing interconnections that link different hardware components of classical and quantum circuits in the example in FIG. 1A, 1C or 1D. The system example in FIG. 1E includes at least one classical non-quantum digital processing module 108 labeled as “Classical Processor Chip,” at least one SFQ repeater as part of the interconnection circuitry or module 106, at least one classical superconducting controller as part of the quantum bit management circuit module 104, which controls the quantum computing processor or module 102 with multiple qubit circuits or devices.

The interconnections in FIG. 1E are designed to include superconducting connection nodes or pads 140 and superconducting connection cables 150 for connecting the classical circuits 104, 106 and 108 and the quantum computing processor or module 102. As illustrated, superconducting connection nodes or pads 140 may be implemented as superconducting bumps in direct contact with one or more hardware components (102, 104, 106, 108) to be connected and can be used to provide connection between a hardware component and a superconducting cable. As explained with reference to FIG. 1A, the quantum computing module 102 and the quantum bit management circuit module 104 can be placed adjacent to each other to allow short connection paths between them for fast inter-module communications and can be thermally coupled to the same cryogenic stage at the same low cryogenic temperature. Notably, the communication links or loops between the classical superconducting controller as part of the quantum bit management circuit module 104 and the quantum processor chip 102 should be fast communication links or loops and superconducting bumps can be used for interconnecting the two modules 102 and 104 to enable fast exchange of information for quantum computing operations and readout. In some implementations, the quantum bit management circuit module 104 containing the classical controller chip can be positioned on the cold plate of a cryocooler immediately above or below the quantum computing module 102 to reduce noise and interference to the quantum computing operations by the qubit circuits or devices inside the quantum computing module 102. In some implementations, superconducting bumps can be configured or used in the form of fences or walls which produce compartments separating strip or microstrip lines or other on-chip transmission lines, as well as qubits or systems of multiple qubits from each other, in order to reduce the mutual crosstalk between the superconducting electronic elements or systems and to improve the quality factors of resonators.

In addition to direct electrical connections between the quantum computing module 102 and the quantum bit management circuit module 104, non-contact connections may be used to achieve the fast communications, including, for example, the differential capacitive coupling between the qubits and the passive transmission lines and magnetic coupling, both of which provide communication links without direct connections and allow for compensation of the geometric misalignments between the modules 102 and 104 and other components as a result of the fabrication process.

The quantum computing operations by qubit circuits or devices inside the quantum computing module 102 are different from a classical computer based on a deterministic Turing machine and Boolean bits of “0” and “1” states and use quantum-mechanical phenomena such as superposition of “0” and “1” qubit states, entanglement between qubits, and interference between probability amplitudes of non-deterministic measurement outcomes to perform computing operations. Superconducting qubits inside the quantum computing module 102 can be implemented by superconducting Josephson junctions. A Josephson junction is a system consisting of weakly coupled superconductors exhibiting correlated, or coherent, states and behaves like a non-linear inductor which allows for building a quantum an harmonic oscillator. The two discrete energy level states of this an harmonic oscillator and their quantum superposition are used to create a qubit. Using Josephson junctions, several versions of superconducting qubits can be constructed, such as transmon, xmon, quantronim, fluxonium, etc.

The state of a qubit is controlled by applying a microwave signal to the qubit. In various implementations, the microwave signal generators may be room-temperature devices, whereas the quantum circuits comprising qubits operate at very low cryogenic temperatures in order to reduce undesired decoherence of qubits. Specifically, the wiring needed to provide microwave signals to qubit circuits may involve different segments maintained different temperatures from the room temperature to the lowest temperature at the cryogenic stage where a quantum circuit is situated, and thus may cause or introduce undesired electric noise, or excessive heat load. Such wiring for a significant number of qubit circuits may occupy a lot of space. Those factors can lead to undesired decoherence of qubit quantum states and pose a significant problem for scaling up the quantum computer. In order to overcome this problem, various techniques may be used to control the qubits in a fully integrated, cryogenic, hybrid quantum-classical processor as shown in FIGS. 1A-1E, including, for example, integration of superconducting qubits with classical superconducting digital logic families such as reciprocal-quantum-logic (RQL) as disclosed by Quentin P. Herr and Anna Y. Herr in an article entitled “Ultra-low-power superconductor logic,” J. Appl. Phys. 109, 103903 (2011), a use of adiabatic quantum-flux-parametrons (AQFP) disclosed by 0. Chen, R. Cai, Y. Wang, F. Ke, T. Yamae, R. Saito, N. Takeuchi, and N. Yoshikawa in an article entitled “Adiabatic Quantum-Flux-Parametron: Towards Building Extremely Energy-Efficient Circuits and Systems,” Sci. Rep. 9, 10514 (2019), or the use of single-flux quantum (SFQ) technology disclosed by O. A. Mukhanov in an article entitled “Energy-Efficient Single Flux Quantum Technology,” IEEE Trans. Appl. Supercond. 21, 760 (2011). As part of the interconnection design for the systems in FIGS. 1A-1E, the control of qubits can be implemented via an SFQ system to control the state of a qubit by applying a sequence of the SFQ pulses without the conventional use of microwave signals as disclosed in U.S. Pat. No. 9,425,804. Techniques for applying flux to a quantum-coherent superconducting circuit in U.S. Patent Application Publication No. US 2015/0263736A1 for “Systems and methods for applying flux to a quantum-coherent superconducting circuit” by inventors Quentin P. Herr, Ofer Naaman and Anna Y. Herr and assignee Northrop Grumman Systems may also be implemented. The readout of qubits may be implemented by quantum electrodynamics measurements disclosed in U.S. Pat. No. 9,692,423 for “System and method for circuit quantum electrodynamics measurement” by Robert Francis McDermott et al. and Applicants Universitaet des Saarlandes, Syracuse University and Wisconsin Alumni Research Foundation. Cryogenic CMOS (cryoCMOS) techniques may also be implemented in the systems in FIGS. 1A-1E for controlling superconducting qubits. See examples disclosed by E. Charbon, F. Sebastiano, A. Vladimirescu, H. Homulle, S. Visser, L. Song, and R. M. Incandela. in their article entitled “Cryo-CMOS for quantum computing” in Technical Digest—International Electron Devices Meeting, IEDM (2017), pp. 1-13 (doi: 10.1109/IEDM.2016.7838410), and by J. C. Bardin et al. in their article entitled “A 28 nm Bulk-CMOS 4-to-8 GHz 2 mW Cryogenic Pulse Modulator for Scalable Quantum Computing”, IEEE J. Solid-St. Circuits 54, 3043-3060 (2019). Those references are incorporated by reference as part of the disclosure of this patent document.

Practical implementations of the systems in FIGS. 1A-1E require careful designs for the interconnections or interface between the quantum circuits of the quantum computing module 102 situated at a low cryogenic temperature (e.g., a certain millikelvin temperature) and classical processing circuits situated at higher temperatures (including the liquid helium temperature). The interconnections in the example in FIG. 1E include placing the quantum computing module 102 and the quantum bit management circuit module 104 next to each other on the same cryogenic stage of the dilution refrigerator without using any superconducting cables or wires 150 between the modules 102 and 104. Instead, superconducting bumps or pads 140 are used to physically join or bind the two modules 102 and 104 together. The signal paths between the two modules 102 and 104 can be implemented in various ways, include signaling via conductive paths formed though the superconducting bumps or pads 140 between the modules 102 and 104, or signaling via capacitive and/or magnetic coupling between the modules 102 and 104. The signal paths between the two modules 102 and 104 are designed to minimize the signal transmission time (e.g., by reducing or eliminating the amount wiring between the modules 102 and 104) and to form the fast communication links or loops in the system as explained above with respect to FIG. 1A.

In implementations where the two modules 102 and 104 are supported by two IC chips, the two chips may be stacked over each other and bonded to form a multichip module (MCM) which is, as an integrated unit, coupled to the same low temperature cryogenic stage so both modules 102 and 104 are operated under the same low cryogenic temperature. Superconducting bumps or pads 140 may be used as part of the binding of the two IC chips or modules 102 and 104. The interconnections in the example in FIG. 1E also implements combinations of superconducting bumps or pads 140 and superconducting cables or wires 150 where the superconducting bumps or pads 140 are used at terminals of the superconducting cables or wires 150 for connecting the wire terminals to devices. For example, in FIG. 1E, the quantum bit management circuit module 104 is shown to be connected to an interconnection circuitry or module 106 such as a digital signal conditioning circuit module via superconducting cables or wires 150 where two sets of superconducting bumps or pads 140 are used to join the two end terminals of each superconducting cable or wire 150 to the contacting points on the quantum bit management circuit module 104 and the corresponding interconnection circuitry or module 106. This use of superconducting bumps or pads 140 and superconducting cables or wires 150 can be applied to connections for other modules such as the connection between the digital processing module 108 and a corresponding interconnection circuitry or module 106 and a connection between different stages or digital signal conditioning circuit modules of the interconnection circuitry or module 106. As illustrated, such superconducting cables or wires 150 with superconducting bumps or pads 140 constitute part of the medium communication links and loops as explained above with respect to FIG. 1A.

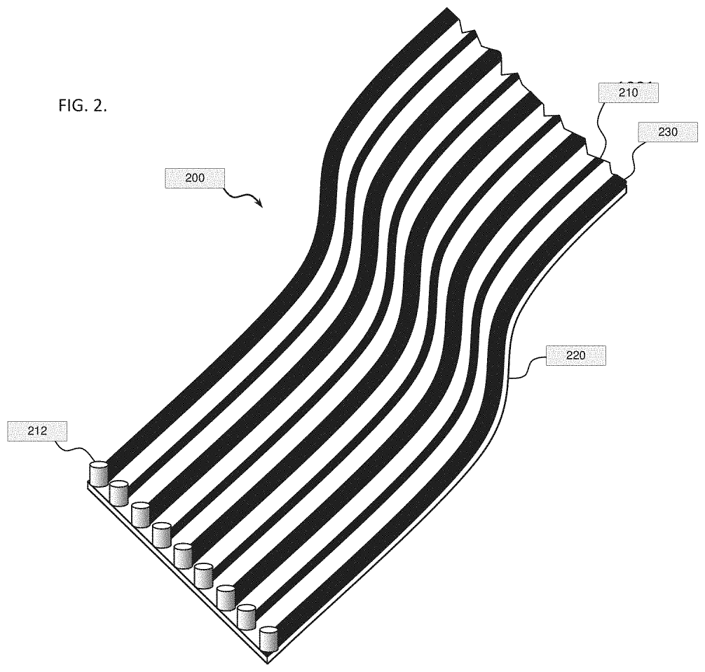

FIG. 2 shows an example of a portion of a flexible ribbon cable 200 having superconductive strip lines and superconducting contact bumps in one implementation of the interconnection 150 shown in FIG. 1E. This exemplary flexible ribbon cable 200 includes electrically conductive cables 210 that are either superconducting strip- or microstrip lines (made of, e.g., Nb or NbTi among other suitable conductive metal materials) that are supported by or engaged to a flexible non-conductive flexible substrate or tape 220 such as a Kapton tape. The superconducting cable 200 further includes electrically conductive bumps 212 serving to connect the cables 210 to an electronic circuit(s) situated on the solid-state (typically Si) chips or modules 102, 104, 106 and 108 in FIGS. 1A-1E. This bump 212 corresponds to the bump 140 in FIG. 1E. The superconducting cable 200 further comprises superconductive metallization 230, typically serving as a ground electrode. Using high-bandwidth superconducting cables could allow for sending microwave signals and Single Flux Quantum (SFQ) pulses between the different temperature stages (for example, between 3K and 20 mK stages in the dilution fridge) with minimal thermal conductivity. Specifically, NbTi has very low thermal conductivity, and with 50 μm wide microstrip lines, the estimated thermal load is on order 40 μW. It is known that an SFQ pulse will not be able to stay intact over a large distance between the highest temperature and the lowest temperature stages due to dispersion and attenuation in the cable. Therefore, the shorter cable segments between 3K, 700 mK, 100 mK, and 20 mK stages that typically are present in the dilution fridge will be used, i.e. between 3K-to-700 mK cable segment #1, between 700 mK-to-100 mK cable segment #2, and between 100 mK-to-20 mK cable segment #3. The combination of superconducting cables and intermediate repeaters may be used to achieve a significant increase in wiring density and thus advantageously reduce the volume or space needed for such wiring within a cryostat.

Additional examples for superconducting cables suitable for implementing the disclosed technology include a pin-chip bonding to provide a fully vertical interconnect using rectangular coaxial ribbon cables for a large array of superconducting qubits fabricated on a single Si or sapphire chip where signal transmission from DC to around 10 GHz, both at room temperature and at cryogenic temperatures down to around 10 mK. One example for implementing such pin-chip bonding which can be found in “High-Density Qubit Wiring: Pin-Chip Bonding for Fully Vertical Interconnects” by M. Mariantoni and A. V. Bardysheva in Quantum Physics in 2020, at arxiv.org/pdf/1810.08580.pdf and arxiv.org/abs/1810.08580, which is a 8-page document and is incorporated by reference as part the disclosure of this patent document.

To minimize the dispersion and attenuation in the cable segments as shown in FIG. 2 and in other cable implementations, each cable segment can be bump-bonded to circuit modules or chips with the electronic superconducting circuits such as the classical control circuits in the quantum bit management circuit module 104 and interconnection circuitry or module 106 (which includes, e.g., the SFQ pulse regenerator/repeaters) using the superconducting contact pads or bumps. The classical controller chip for the quantum bit management module 104 and the quantum chip 102 may be placed at the cold stage of the dilution refrigerator and may be directly bump-bonded via the superconducting contact pads (bumps) on both chips using an MCM technique. The superconducting contact pads (bumps) may be structured to include indium that is mechanically soft and has the superconducting transition temperature of 3.4 K. Alternatively, non-superconducting bump bonds may also be used to bind classical controller chip 104 and the quantum chip 102, and the classical chip 104 may be further connected via superconducting or non-superconducting cables (coaxial or ribbon cables) to other classical chips.

In some implementations, the ribbon cable can be connected by connecting to a special impedance converter wafer or chip (e.g. from 50 to 20 Ohm), which in turn is bump-bonded to the classical chip. The quantum chip can be connected to other quantum chips without breaking quantum coherence between the chips using microwave waveguides or other types of quantum links. Both surfaces of each chip (quantum and classical) can be used for forming circuits. These circuits can be interconnected using (e.g., superconducting) through-silicon vias (TSVs) and bump-bonds.

The aforementioned direct bump-bonding has a number of advantages and serves for the following purposes: (1) Establishing mechanical connection between the quantum chip 102 and the classical controller chip 104; (2) Minimizing the noise influence to the quantum chip 102 and for minimizing the communication time between the classical controller chip 104 and the quantum chip 102; (3) Setting the specified and uniform (same distance across the chip) distance between the chips 102 and 104 in order to establish reproducible and unchangeable during operation coupling capacitances and mutual inductances between circuits on both chips; (4) Providing galvanic connection between the grounds on both chips 102 and 104 to form a common ground between them; (5) Providing galvanic connections of signal lines to form superconducting lossless loops between the chips 102 and 104. These loops can be used to deliver constant or switchable electric current, including the current for providing the magnetic flux bias for qubits and couplers between qubits; (6) Providing galvanic connection between chips for transmitting SFQ pulses between chips; (7) Providing galvanic connection to form a single superconducting circuit comprising elements on both chips.

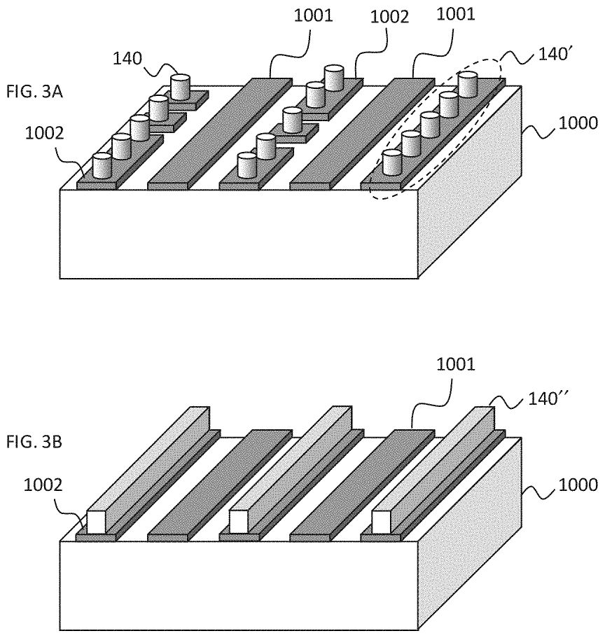

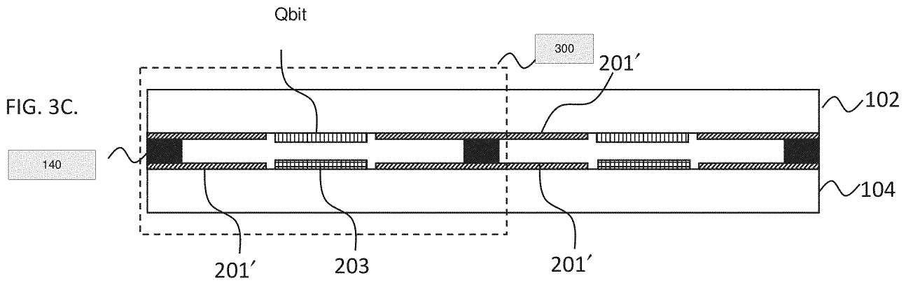

The common ground and the arrangements and design of the superconducting bumps 140 can be done in arrays, fences, walls, etc. Referring to FIG. 3A, shown is a schematic perspective view of a part of a chip 1000 (typically made of Si) comprising transmission line structures 1001 and bumps 140 which reside on metallizations 1002; some of the metallizations 1002 may be connected to the ground plane of chip 1000, while others may be connected to other parts of the circuits on the chip 1000. In yet other applications including applications when using TSVs and bump-bonds, the metallizations 1002 may not be present.

The bumps 140 create fences 140′ which improve electromagnetic isolation between the transmission line structures 1001 and reduce the crosstalk between them. In some implementations, instead of the multitude of bumps 140, the fences can made as continuous walls 140″, as is schematically shown in FIG. 3B for the same type of transmission line structure. Also, in various implementations, the fences 140′ or walls 140″ can be positioned either on quantum chip 102 or classical chip 104.

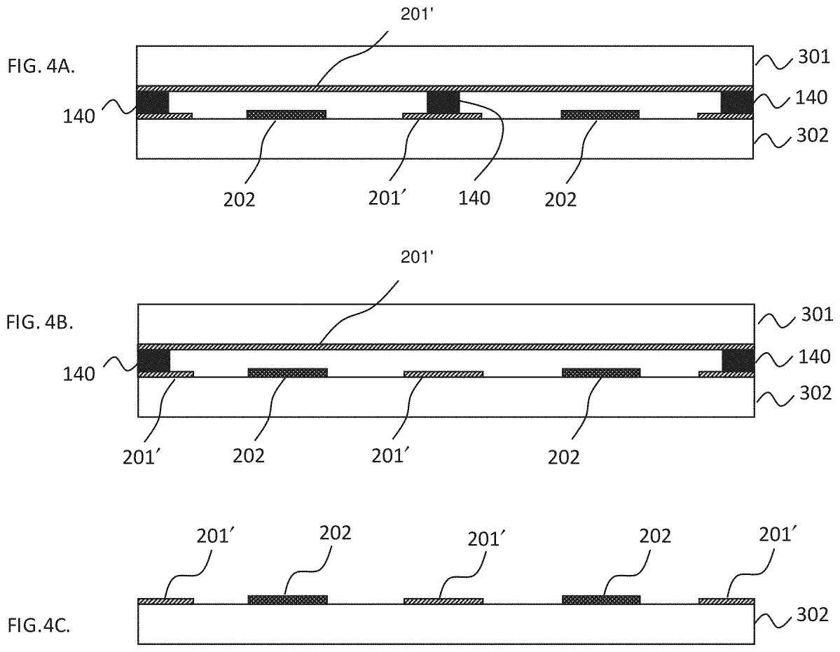

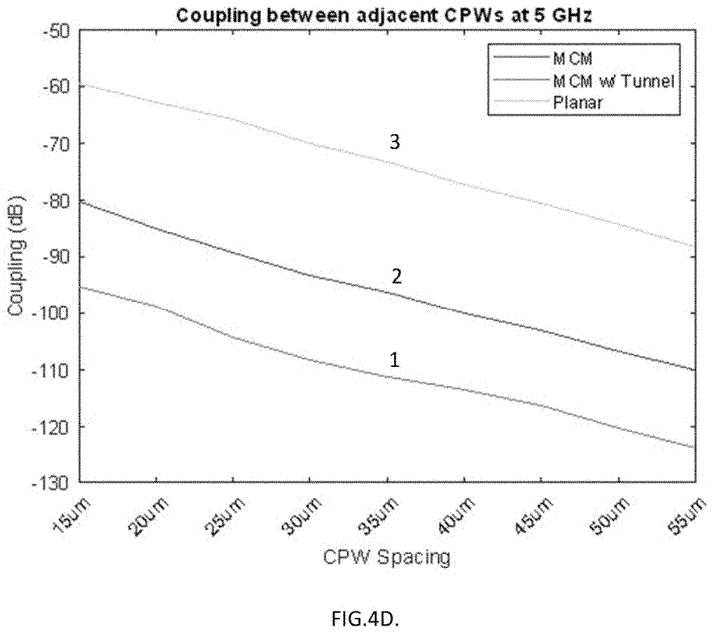

FIG. 3C shows an example in which superconducting fences 140′ or walls 140″are used to form 3D compartments 300 each comprising one or more qubits, classical circuits 203, and superconductive metallization 201′, which is schematically shown in FIG. 3C as a cross-section of a part of an MCM structure. Such setup results in better electromagnetic isolation of the qubits from each other (in other words, reducing the crosstalk) and increasing the quality factor of the resonators incorporating the qubits or connected to the qubits. This is further explained through simulation results presented in FIG. 4D.

FIG. 4A schematically shows a cross-section of a segment of an example of a suitable MCM structure with two chips 301 and 302, the two chips being mechanically and electrically connected via bumps 140. The top chip 301 has metallization 201′ in the form of a superconductive thin film. The bottom chip 302 has transmission lines 202 and sections of metallization 201′ which serves as the ground plane for the transmission lines 202. The transmission lines 1001 in FIGS. 3A-3C and transmission lines 202 in FIGS. 4A-4C are shown as an example; in general, other circuits (both classical and quantum circuits) or circuit elements may be represented by the parts 1001 and 202. The central section of the metallization 201′, separating the two transmission lines 202, is connected via bump 140 to the metallization 201′ on the top chip.

FIG. 4B shows another example with a similar structure as in FIG. 4A with a modification: the bump 140 connecting the central section of the metallization 201′ on the bottom chip to its counterpart 201′ on the top chip, is absent. FIG. 4C shows a cross-section of a segment of the bottom chip with the transmission lines 202 and metallization 201′ without any bumps 140.

FIG. 4D shows a result of simulated coupling between the transmission lines 202 for each of the three cases mentioned above. Curves 1-3 in the FIG. 4D correspond to the cases depicted in FIGS. 4A, 4B, and 4C, respectively. One can infer from these plots that minimum coupling (best result) is obtained for the structure shown in FIG. 4A, where the transmission lines 202 are separated from each other by the fence created by the bumps 140. Similar situation, i.e., reduction of the crosstalk, will be realized in more complicated circuits, specifically, if the quantum circuits are separated from each other by the fences 140′ or continuous walls 140″.

The aforementioned coupling of the classical controller chip 104 and the quantum chip 102 in the form of MCM can be advantageous in some implementations for one or more reasons: (i) the above chip to chip bonding allows the classical control chip 104 and the quantum chip 102 to be made using different technologies that may not be well compatible with each other. Separate fabrication of these chips 104 and 102 allows chips 104 and 102 to be made with most advanced fabrication technologies individually with high quality; (ii) it is determined experimentally that, if both the classical control circuit 104 and the quantum circuit 102 are fabricated on the same chip, the quantum chip 102 may suffer from quasiparticle poisoning from the classical control chip 104, which leads to enhanced decoherence; (iii) Input-output signals between the room-temperature electronics and MCM, or between the repeaters and MCM, can be accomplished by way of connecting the appropriate cables to the classical control chip 104, which reduces the influence of the electrical noise from the higher-temperature stages of the setup to the quantum chip 102.

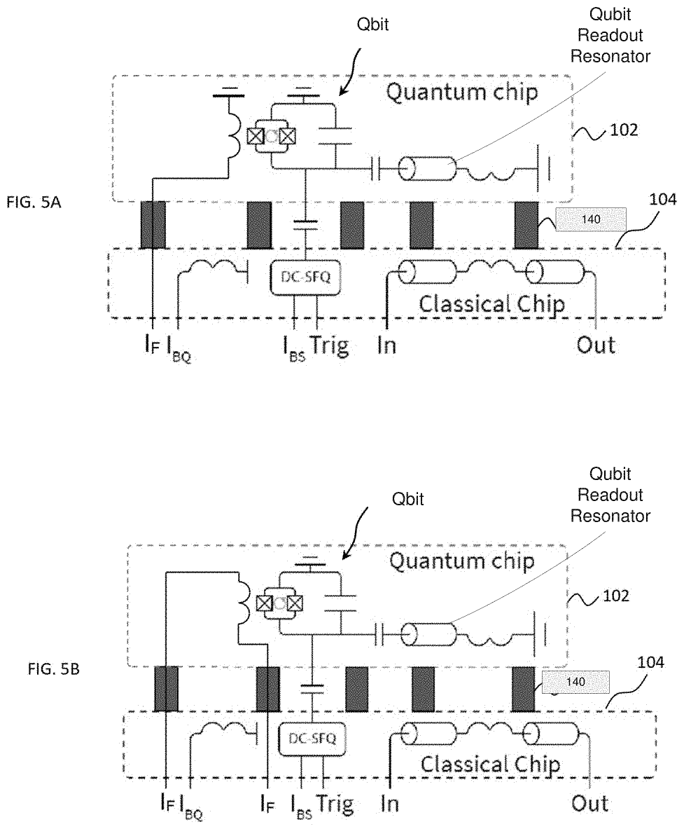

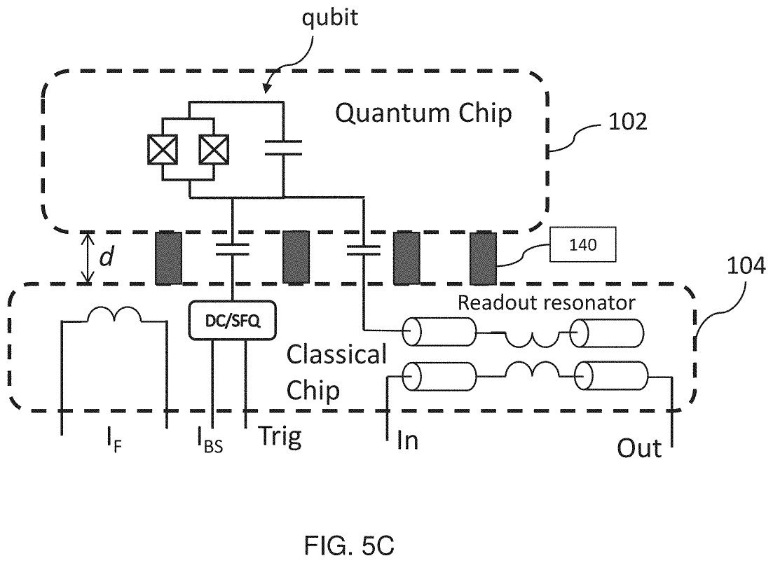

An example for implementing such a MCM for the chips 102 and 104 is shown in FIGS. 5A and 5B. As illustrated, a top quantum chip 102 contains qubit circuits and the readout resonators. The bottom classical chip 104 includes the SFQ circuitry and a feedline to couple to the qubit resonator for each qubit. A current bias line, I_{BQ} or I_{F}, is used to provide a flux bias current to each qubit. This flux bias current can be provided through an inductive coupling across the gap between the classical chip 104 and quantum chip 102, as illustrated by current bias line I_{BQ}. Alternatively, the current bias line can extend from the classical chip 104 to the quantum chip 102 through the bump(s) 140 so that the inductor coupled to the qubit to provide the flux bias resides on the quantum chip 102 with the qubit, as illustrated by current bias line I_{F}. Current bias line I_{F} can be configured asymmetrically, as shown in FIG. 5A, or symmetrically, as shown in FIG. 5B. Superconducting indium bumps 140 also connect the ground planes of the two chips 102 and 104. Other configurations of the MCM module are possible.

FIG. 5C shows another example for implementing an MCM assembly for chips 104 and 102 in which the readout resonator for each qubit is located on the classical chip 104 as opposed to the configurations described above in which qubits and readout resonators are integrated together on quantum chip 102. In various implementations, a superconducting qubit can be coupled to an electromagnetic resonator for readout based on that the state of the qubit (ground or excited) induces a shift in the resonance mode of the electromagnetic resonator. The qubit and the readout resonator can both be planar and fabricated on the same chip as disclosed in an article entitled “Strong coupling of a single photon to a superconducting qubit using circuit quantum electrodynamics” by Wallraff, A., Schuster, D. I., Blais, A., Frunzio, L., Huang, R. S., Majer, J., Kumar, S., Girvin, S. M., & Schoelkopf, R. J. in Nature, 431(7005), 162-167 (2004). Alternatively, various quantum circuit designs seek to take advantage of having as much electromagnetic field density as possible in lossless vacuum by coupling the qubit to 3D resonance modes such as those in 3D cavities or resonators as described in an article entitled “Observation of High Coherence in Josephson Junction Qubits Measured in a Three-Dimensional Circuit QED Architecture” by Paik, H., Schuster, D. I., Bishop, L. S., Kirchmair, G., Catelani, G., Sears, A. P., Johnson, B. R., Reagor, M. J., Frunzio, L., Glazman, L. I., Girvin, S. M., Devoret, M. H., & Schoelkopf, R. J. in Physical Review Letters, 107(24), 240501 (2011).

One way for implementing the design in FIG. 5C is to design both the qubit and readout resonator in a planar, 2-dimensional (2D) configuration for each circuit while fabricating each qubit and its corresponding readout resonator on different substrates and packaging and stacking them in an MCM, so that they lie in different XY planes, separated by an inter-chip distance d along the Z axis. In this design, while individual elements (e.g., each qubit and its corresponding readout resonator) are 2D components each residing entirely on its own substrate, the device or module integration density is increased by coupling different 2D components or circuits in a 3-dimensional (3D) manner so that mode coupling is an out of plane coupling—between the planar qubit circuit to a matching planar readout resonator. This configuration combines 2D components stacked in a 3D configuration and thus may be referred to as a “2.5D” architecture. Under this “2.5D” design, the planar readout resonators exist entirely on the classical chip and thus exhibit 2D modes in the plane of the classical chip independent of the quantum chip that includes the corresponding qubits. When planar readout resonators are brought in proximity to the quantum chip as in the MCM, there is a small out of plane component that provides coupling between a qubit and its corresponding readout resonator, though the majority of the readout resonator mode is still 2D in the plane of the classical chip. This design is advantageous because of the simplicity of fabrication of 2D circuits or components, design flexibility and/or increased density of integration.

Specifically, the example in FIG. 5C schematically illustrates a transmon qubit in the quantum qubit chip 102 is capacitively coupled to a corresponding readout resonator in the classical chip 104, where the coupling takes place between the two capacitor pads separated by inter-chip distance d. The readout resonator may be implemented, for example, as a meandered coplanar waveguide (CPW) resonator or a lumped element resonator. Other qubit varieties, such as fluxonium, C-shunted flux qubit (CSFQ), Cooper Pair Box, or other qubits along the charge/flux spectrum. Additionally, the coupling across the gap may be capacitive or inductive in nature.

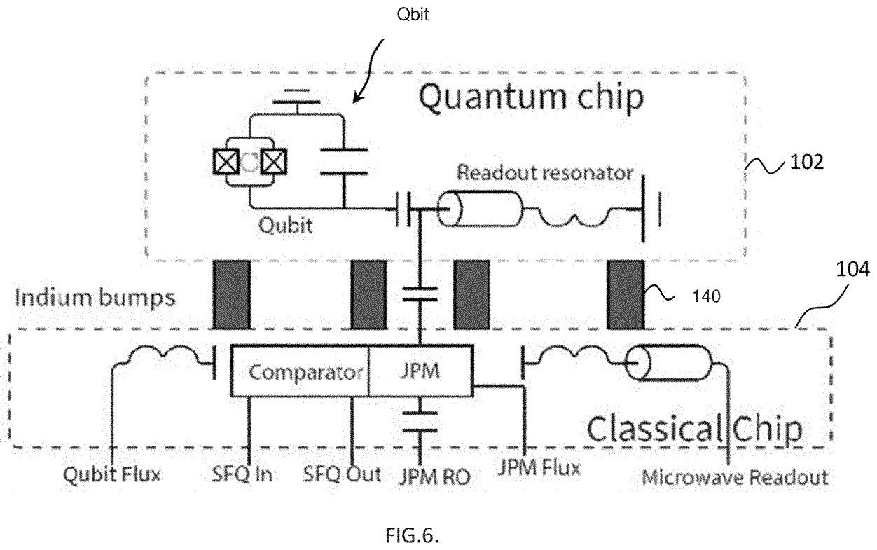

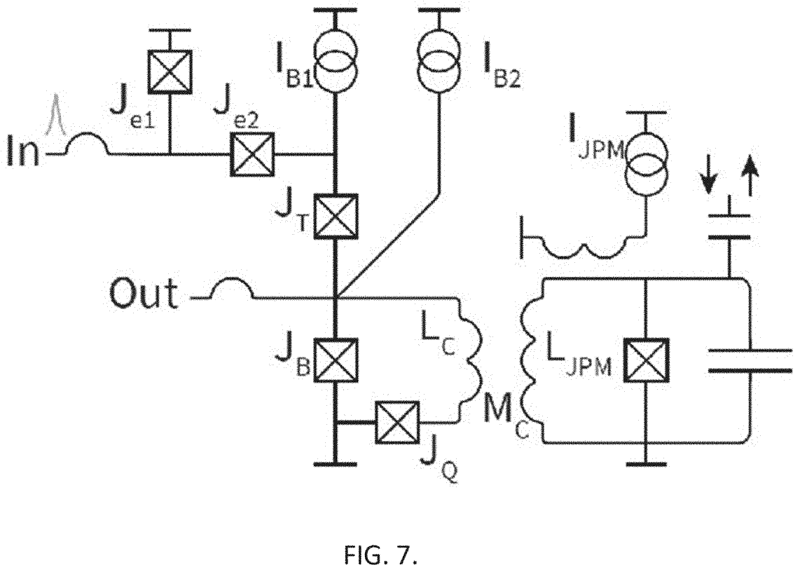

The two substrates for respectively supporting the qubit in the chip 102 and the readout resonator in the chip 104 may be connected by bump bonds 140. In implementations where the coupling between the qubit and the readout resonator are via capacitive or inductive coupling, these bonds 140 may be implemented to provide a purely mechanical connection or engagement, meaning that the qubit can be electrically isolated from the resonator ground plane and thus called “floating qubit”. Alternatively, the bump bonds may provide a superconducting connection between ground planes on both substrates so that each qubit is a “grounded qubit”. In various implementations, the classical controller chip 104 may include electronic circuits suitable for fast exchange of information between the chip 104 and the quantum chip 102. FIG. 6 shows an example of the MCM containing the classical controller chip 104 and the quantum chip 102. In FIG. 6, a qubit and a readout resonator are fabricated on a top quantum chip 102. A Josephson photomultiplier (JPM) and a reflectometry port are fabricated on the bottom classical controller chip 104. The JPM is coupled to an SFQ comparator with a digital trigger in and digital result out. For example, the comparator may be implemented as a standard SFQ circuit element used mainly in SFQ analog-to-digital converters. All flux lines for JPM and qubit are on the classical controller chip 104. A readout (RO) port is also added to measure the readout resonator with microwaves. A more detailed layout of a JPM-SFQ comparator circuit is shown in an example in FIG. 7. As shown by the right-hand side of FIG. 7, a loop is made from the bottom comparator junction in order to convert a flux into a current. This loop is coupled to the JPM inductor with a mutual inductance M_{c}. Another small junction J_{Q} is added to the loop in order to clear out any residual flux left in the loop as a result of switching. Two bias currents from current sources I_{B1} and I_{B2} are used to tune the phases of the two comparator junctions.

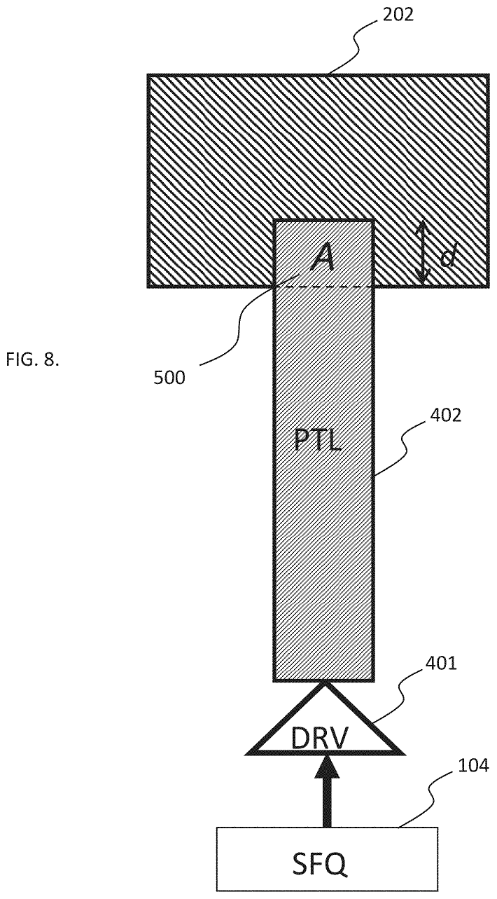

FIG. 8 show an example of a circuit design for improving the capacitive coupling between the classical SFQ chip 104 and the qubit that belongs to the quantum chip 102. FIG. 8 schematically shows the abovementioned capacitive coupling. An SFQ signal from the classical chip 104 is delivered to the qubit via a driver 401, a passive transmission line (PTL) 402, and a capacitor 500 created by an overlapped area A of a part of PTL and a part of the qubit 202. The capacitance Cₘ of this capacitor 500 is proportional to the area A and, therefore, to the distance d to which the PTL 402 extends into the appropriate part of the qubit. Due to non-ideal reproducibility of the technological conditions, this distance d may vary from one fabrication run to another, which results in undesirable variations of the coupling capacitance δCₘ∝δd.

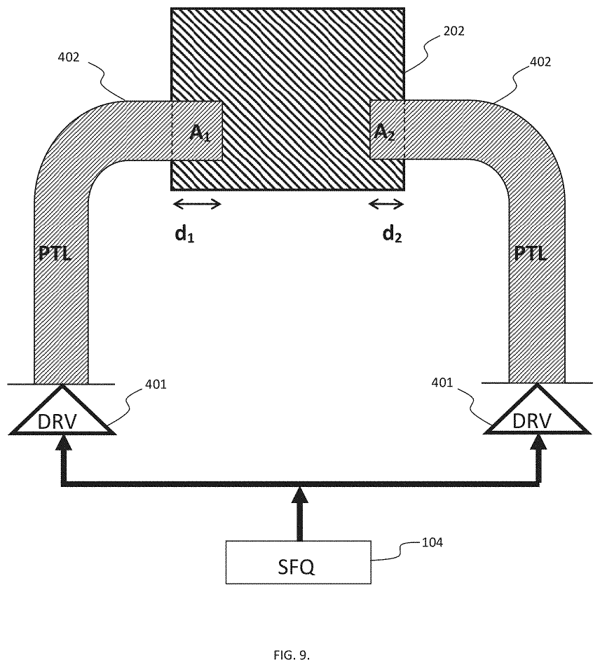

FIG. 9 shows an alternative implementation to FIG. 8 to overcome the abovementioned drawback in the design in FIG. 8. The design in FIG. 9 uses two passive transmission lines (PTLs) 402 to provide capacitive coupling to reduce, variations in the capacitive coupling caused by the misalignments between the PTL 402 and the appropriate part of the qubit in the design in FIG. 8. FIG. 9 uses the capacitive coupling by two capacitors formed by the overlapping areas A₁ and A₂. Of the two PTLs 402 with the conductive plane in the quantum chip 202, where the total coupling capacitance Cₘ is the sum of the two capacitors represented by the overlapping areas A₁ and A₂, and therefore, will be preserved regardless of actual positioning d₁, d₂ due to the following relations: Cₘ∝A₁+A₂∝d₁+d₂; δCₘ∝δ(d₁+d₂)=0. An advantage of the coupling design in FIG. 9 is reproducibility of the coupling capacitance for devices fabricated in different runs, which is important to establish reproducible qubit control.

The above examples for disclosed quantum computing systems provide unique interconnection designs for different modules to allow practical and scalable implementations based on new system designs and new interconnection designs that reduce or eliminate direct wiring connections between room temperature and the cold stage where the quantum chip is situated. Multiplexing and demultiplexing circuits can be placed on the quantum bit management module and digital processing modules to allow each signal line to carry signals to/from multiple qubits in the quantum array, thus reducing the amount of wiring required between modules. The disclosed system designs and interconnections would allow quantum computing systems to be scaled with different quantum computing power for different applications. In implementations, qubit control can be implemented by SFQ control and by placing the SFQ control chip in close proximity to the quantum circuit chip with suitable interconnections operating at different cryogenic temperatures, e.g., from liquid He temperatures for classical non-quantum processing circuits or modules and to millikelvin temperatures for one or more quantum circuits or processors.

Implementations of various features disclosed in this patent document may be based on what is disclosed in this patent document in light of various technical features in the following published references which are incorporated by reference as part of the disclosure of this patent document:

1. “Energy-Efficient Single Flux Quantum Technology” by Oleg A. Mukhanov in IEEE TRANSACTIONS ON APPLIED SUPERCONDUCTIVITY, VOL. 21, NO. 3, JUNE 2011.

2. “Cryo-CMOS for Quantum Computing” by Charbon et al. in IEEE, 2016.

3. “Design and Characterization of a 28-nm Bulk-CMOS Cryogenic Quantum Controller Dissipating Less Than 2 mW at 3 K” by Leonard Jr. et al., in IEEE JOURNAL OF SOLID-STATE CIRCUITS, VOL. 54, NO. 11, NOVEMBER 2019.

4. “Digital Coherent Control of a Superconducting Qubit” by Bardin et al., in PHYSICAL REVIEW APPLIED 11, 014009 (2019).

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples are described and other implementations, enhancements and variations can be made based on what is described and illustrated in this patent document.

1. A system capable of information processing based at least in part on quantum computing using quantum states of quantum bits, comprising:
a cryostat system structured to include different cryogenic stages operable to provide a low cryogenic temperature and higher cryogenic temperatures;
a quantum computing module enclosed by the cryostat system at the low cryogenic temperature, the quantum computing module comprising a first integrated chip structured to support a plurality of quantum bit circuits, wherein each quantum bit circuit is structured as a superconducting circuit at the low cryogenic temperature to exhibit different quantum states as a quantum-mechanical system and to quantum-mechanically interact with other quantum bit circuits via quantum entanglement to cause superposition or correlation of different quantum states of the quantum bit circuits;
a quantum bit management circuit module enclosed by the cryostat system, located adjacent to the quantum computing module and coupled to be maintained at a cryogenic temperature, quantum bit control circuits supported by a second integrated chip and structured to direct control signals to the quantum bit circuits to control the quantum bit circuits, respectively, and quantum bit readout circuits supported by the second integrated chip and structured to output readout signals from the quantum bit circuits, respectively, the readout signals representing quantum states of the quantum bit circuits, respectively, the quantum bit control circuits and quantum bit readout circuits structured to include superconducting circuits at the low cryogenic temperature and operable to operate with the control signals and readout signals based on digital processing and in a non-quantum classical manner, and wherein the second integrated chip is engaged to the first integrated chip to form a multichip module to transfer control signals and readout signals therebetween;
circuit modules enclosed by the cryostat system at the higher cryogenic temperatures and structured to communicate with the quantum bit management circuit module in connection with the control signals and readout signals;
electrically conductive bumps formed to engage the first and second integrated chips to each other; and
electrically conductive wires coupled between the quantum bit management circuit module and at least one of the circuit modules situated at higher temperature stages of the cryostat system to provide communications and transfer signals therebetween.

2. The system as in claim 1, wherein:
the electrically conductive bumps are to provide mechanical engagement between the first and second integrated chips and are not electrically connected to a circuit in either the first integrated chip or the second integrated chip; and
the quantum computing module and quantum bit management circuit module are coupled to each other to exchange information via conductive or inductive coupling.

3. The system as in claim 1, wherein the electrically conductive bumps are connected so that at least part the electrically conductive bumps form electrical conductive paths between the quantum bit management circuit module and quantum computing module for transfer of part of the control signals and readout signals without using other wiring between the quantum bit management circuit module and quantum computing module.

4. The system as in claim 1, wherein the electrically conductive bumps include electrically conductive isolation bumps located to form isolation fences separating the electrically conductive wires to reduce crosstalk between the electrically conductive wires.

5. The system as in claim 1, wherein the quantum computing module includes electrically conductive isolation bumps located to form isolation fences separating the quantum bit circuits to reduce crosstalk therebetween and to decrease decoherence of the quantum bit circuits.

6. The system as in claim 1, further comprising electrically conductive isolation walls located to form isolation walls separating the electrically conductive wires to reduce crosstalk between the electrically conductive wires.

7. The system as in claim 1, wherein the quantum computing module includes electrically conductive isolation walls separating the quantum bit circuits to reduce crosstalk therebetween and to decrease decoherence of the quantum bit circuits.

8. The system as in claim 1, wherein the quantum bit management circuit module and quantum computing module are structured to include capacitive coupling circuitry to enable capacitive coupling between the quantum bit management circuit module and quantum computing module to provide signaling separate from the electrical conductive paths formed by electrically conductive bumps.

9. The system as in claim 1, wherein the quantum bit management circuit module and quantum computing module are structured to include magnetic coupling circuitry to enable magnetic induction coupling between the quantum bit management circuit module and quantum computing module to provide signaling separate from the electrical conductive paths formed by electrically conductive bumps.

10. The system as in claim 1, further comprising a flexible non-conductive material on which the electrically conductive wires are formed and separated from one another so that the flexible non-conductive material and the electrically conductive wires form a flexible ribbon that connects at least one of the circuit modules and the quantum bit management circuit module.

11. The system as in claim 1, wherein:
each quantum bit circuit includes a superconducting Josephson junction circuit at the low cryogenic temperature.

12. The system as in claim 1, wherein:
the quantum bit management circuit module includes a superconducting switching circuit that is different from a Josephson junction circuit.

13. The system as in claim 1 wherein:
the quantum bit management circuit module includes a Josephson junction circuit.

14. The system as in claim 1, wherein:
the quantum bit management circuit module includes a single flux quantum (SFQ) logic circuit.

15. The system as in claim 1, wherein:
the quantum bit management circuit module includes a quantum flux parametron circuit.

16. The system as in claim 1, wherein:
the quantum bit management circuit module includes a nanowire switch.

17. The system as in claim 1, wherein:
the quantum bit management circuit module includes a superconducting ferromagnetic transistor.

18. The system as in claim 1, wherein:
the quantum bit management circuit module includes a superconducting spintronic device.

19. The system as in claim 1, wherein:
the quantum bit management circuit module includes a field-effect superconducting device.

20. The system as in claim 1, further comprising:
optical transmitter and receiver devices to enable transmission and reception of optical signals between the cryogenic stages situated at the highest temperature of the cryostat system and the room temperature electronics to provide communications therebetween.

21. The system as in claim 1, wherein the quantum bit management circuit module and the quantum computing module are maintained at the same low cryogenic temperature.

22. The system as in claim 1, wherein:
the quantum computing module further comprises a plurality of readout resonators supported by the first integrated chip and structured to interact with the plurality of quantum bit circuits, respectively, to produce quantum bit circuit readout signals; and
the quantum bit readout circuits supported by the second integrated chip and structured to interact with the plurality of readout resonators supported by the first integrated chip, respectively, to receive the quantum bit circuit readout signals, respectively, and output the readout signals, respectively.

23. The system as in claim 1, wherein:
the quantum bit readout circuits supported by the second integrated chip are structured to include a plurality of readout resonators supported by the second integrated chip and structured to interact with the plurality of quantum bit circuits supported by the first integrated chip, respectively, to produce quantum bit circuit readout signals; and
the quantum bit readout circuits supported by the second integrated chip are structured to interact with the plurality of readout resonators, respectively, to receive the quantum bit circuit readout signals, respectively, and output the readout signals, respectively.

24. A method for processing information processing based at least in part on quantum computing using quantum states of quantum bits, comprising:
operating a quantum computing module comprising a plurality of quantum bit circuits operable to exhibit different quantum states as a quantum-mechanical system to cause to quantum-mechanically interactions amongst the quantum bit circuits to cause superposition or correlation of different quantum states of the quantum bit circuits;
causing quantum bit control circuits to direct control signals to the quantum bit circuits to control the quantum bit circuits, respectively; and
operating quantum bit readout circuits to output readout signals from the quantum bit circuits, respectively, the readout signals representing quantum states of the quantum bit circuits, respectively,
thermally coupling the quantum bit circuits, the quantum bit control circuits and quantum bit readout circuits to a common cryogenic stage;
coupling the quantum bit circuits, the quantum bit control circuits and quantum bit readout circuits via capacitive coupling or inductive coupling to apply the control signals from the quantum bit control circuits to the quantum bit circuits, respectively; and
using electrically conductive wires coupled between the quantum bit management circuit module and one or more circuit modules at one or more higher temperatures than a temperature of the common cryogenic stage coupled to the quantum bit circuits, the quantum bit control circuits and quantum bit readout circuits to transmit information in connection with operating the quantum bit circuits, the quantum bit control circuits and quantum bit readout circuits.

25. (canceled)
